(19) United States
(12) Patent Application Publication
(10) Pub. No.: US 2002/0093052 A1
(43) Pub. Date: Jul. 18, 2002

(54) Semiconductor device

(75) Inventor: Takashi Masuda, Tokorozawa-shi (JP)

Correspondence Address: ARMSTRONG,WESTERMAN & HATTORI, LLP, 1725 K STREET, NW., SUITE 1000, WASHINGTON, DC, 20006, US

(73) Assignee: Citizen Watch Co., Ltd., Nishitokyo-shi (JP)

(21) Appl. No.: 09/978,205

(22) Filed: Oct. 17, 2001

(30) Foreign Application Priority Data
Oct. 23, 2000 (JP) 2000-322220

(51) Int. Cl. H01L 31/0392; H01L 27/12; H01L 27/01

(52) U.S. Cl. 257/347

(57) ABSTRACT

A P component region (2) is formed of a surface silicon layer of an SOI substrate and isolated, and a gate electrode (21) is provided above the P component region (2) with a gate oxidation film (15) therebetween. A lightly doped P region (37) is formed in the P component region (2), an N source region (7) formed of a conduction type different from that of the lightly doped P region (37) and formed shallow in the P component region (2) such that a back surface thereof does not contact a buried oxidation film (19) is provided in the P component region (2), an N offset drain region (9) is provided on the opposite side thereto across the gate electrode (21), a drain region (5) is provided in the N offset drain region (9) in a manner not come into contact with the gate oxidation film (15), and a channel doped layer (25) is provided under the gate oxidation film (15).

### BACKGROUND OF THE INVENTION

1. Field of the Invention

The present invention relates to a semiconductor device using an SOI substrate having an SOI (Silicon On Insulator) structure in which a buried oxidation film and a surface silicon layer are provided on a support substrate made of silicon.

2. Description of the Related Art

The SOI substrate is a semiconductor substrate where a surface silicon layer is formed above a support substrate made of silicon with a buried oxidation film therebetween. The semiconductor device fabricated using such SOI substrate has many advantages as compared with a semiconductor device fabricated with bulk silicon because components can be completely isolated. For instance, these advantages include easy realization of a multi-power source, no occurrence of a latch-up phenomenon (free from latch-up), and so on. A conventional semiconductor device using an SOI substrate has a structure, for example, shown in FIG. 6.

FIG. 6 is a schematic sectional view showing an enlarged principal portion of the conventional semiconductor device. This semiconductor device has a structure such that a silicon film is provided on an insulating layer 102 formed on a support substrate 101 made of silicon, in which the silicon film is partially removed to form a plurality of separate island-shaped component regions 110. Each of the component regions 110 has an N source region 105 and an N drain region 106 respectively on both sides, the right and left sides, of a P channel region 107, and elongate body regions 108 outside the N source region 105 and the N drain region 106 respectively. A gate electrode 111 is provided above the P channel region 107 with a gate electrode film 109 therebetween. The N source region 105 and the N drain region 106 are formed deep such that back surfaces thereof contact the insulating layer 102, and provided with metal electrodes 112 on the top surfaces thereof. Further, each component region 110 is surrounded by an isolation oxide film 103 and an interlayer insulating film 104.

Meanwhile, semiconductor integrated circuit (IC) chips grow in importance as technology for computers and portable devices has advanced in recent years. Some IC chips may be used, as in a liquid crystal display driver, at a high voltage of about 30 V, as compared to that of a Logic IC, for a power source voltage. Since the semiconductor device fabricated using an SOI substrate has advantages such as easy realization of a multi-power source as described above, the IC chip can be increased in value and function by using the SOI substrate for an IC chip for high voltage.

A conventional semiconductor device for high voltage using an SOI substrate is explained here. FIG. 7 is a schematic sectional view showing an enlarged principal portion of the conventional semiconductor device for high voltage. The semiconductor device has a structure such that a silicon film is provided on a buried oxidation film 151 formed on a support substrate 150, and the silicon film is partially removed to form a plurality of separate island-shaped component regions 160 and 190. An N channel field effect transistor (hereinafter referred to as “an N channel FET”) 170 and a P channel field effect transistor (hereinafter referred to as “a P channel FET”) 200 are provided respectively on the component region 160 and the component region 190 isolated from each other by the buried oxidation film 151. In this semiconductor device, a pair of N channel FET 170 and P channel FET 200 constitute a CMOS transistor.

In the N channel FET 170, a P region 154, an N source region 152, a lightly doped P region 155, an N offset drain region 156, and an N drain region 153 are formed in order from the left-hand side of the component region 160 in FIG. 7. A gate electrode 161 is provided to extend over the N source region 152, the lightly doped P region 155, and the N offset drain region 156 through a gate electrode film 162, and metal electrodes 157 are provided on the upper surfaces of the P region 154 and the N source region 152, and the N drain region 153 respectively. In the N channel FET 170, the N source region 152 and the N drain region 153 are formed deep so that respective back surfaces contact the buried oxidation film 151.

In the P channel FET 200, an N region 184, a P source region 182, a lightly doped N region 185, a P offset drain region 186, and a P drain region 183 are formed in order from the left-hand side of the component region 190 in FIG. 7. A gate electrode 191 is provided to extend over the P source region 182, the lightly doped N region 185, and the P offset drain region 186 through a gate electrode film 192, and metal electrodes 187 are provided on the upper surfaces of the N region 184 and the P source region 182, and the P drain region 183 respectively. In the P channel FET 200, the P source region 182 and the P drain region 183 are formed deep so that respective back surfaces contact the buried oxidation film 151.

When the IC chip using the SOI substrate as described above is operated, it is necessary to ground or bias at a predetermined voltage the support substrate (the support substrate 150 in the semiconductor device shown in FIG. 7). This is because the operation of the IC chip can be stabilized.

However, when the support substrate 150 is grounded or biased to drive the IC chip in which the CMOS transistor is formed on the SOI substrate as in the semiconductor device shown in FIG. 7, the support substrate 150 comes to be different in potential from either the component region 160 or the component region 190 in one of the MOSFETs composing the CMOS transistor. For instance, as shown in FIG. 7, when the support substrate 150 is grounded to ground the component region 160, the component region 190 must be set at a power source potential (by an applied voltage VDD). Therefore, a potential difference is caused between the support substrate 150 and the component region 190.

So, the disadvantage due to an occurrence of such potential difference will be explained with reference to FIG. 8 and FIG. 9 showing only an enlarged portion of the P channel FET 200 in FIG. 7. Incidentally, in the sectional views, part of the hatching is omitted for convenience of illustration.

The lightly doped N region 185 and the P source region 182 in FIG. 8 form a PN junction. In the vicinity of the PN junction, electrons as majority carriers in the lightly doped N region 185 and holes as majority carriers in the P source region 182 come into recombination, whereby a depletion layer 193 is formed as shown in FIG. 8.

Normally, the applied voltage VDD is supplied to the P source region 182 and the lightly doped N region 185, and when the value of the applied voltage VDD is increased to the positive voltage side, electrons near a boundary surface 195 between the lightly doped N region 185 and the buried oxidation film 151 are excluded, whereby a depletion layer 194 is formed. When the applied voltage VDD is increased further, an inversion layer 196 composed of holes is formed near the boundary surface 195. In this state, the P source region 182 contacts the inversion layer 196, which causes carriers (holes) 197 to be supplied from the P source region 182 toward the inversion layer 196.

In addition, since the P drain region 183 and the P offset drain region 186 are normally applied with a drain voltage Vd with which they are reverse-biased in relation to the lightly doped N region 185 (see FIG. 7), the carriers (holes) 197 flow from the inversion layer 196 into the P offset drain region 186 if the carriers 197 are continuously supplied, and consequently, a leakage current b appears along the boundary surface 195. Further, since the P source region 182 is formed deep to contact the buried oxidation film 151, which promotes the supply of the carriers (holes) 197. This results in the formation, as a path of current, of a back channel formed by the leakage current b which is not controlled by the voltage applied to the gate electrode 191 in addition to a front channel in which a channel current c flows which is controlled by the applied voltage.

When the leakage current b appears as described above, a current also flows even when a voltage for turning on the front channel is not applied to the gate electrode 191, whereby it becomes impossible to accurately control the current flowing in the MOSFET by the voltage applied to the gate electrode 191. In other words, there is a disadvantage that the leakage current b appears due to the potential difference between the lightly doped N region 185 with the applied voltage VDD and the support substrate 150, resulting in inaccurate control of the current in the MOSFET.

The above disadvantage may arise not only in the P channel FET 200 but also in the N channel FET 170 similarly. In the case of the N channel FET 170 shown in FIG. 7, there is no potential difference between the lightly doped P region 155 and the support substrate 150 by grounding the lightly doped P region 155, and thus there appears no leakage current along the boundary surface between the lightly doped P region 155 and the buried oxidation film 151. However, when the support substrate 150 is set at the power source voltage VDD, a potential difference is caused between the lightly doped P region 155 and the support substrate 150, resulting in appearance of the aforementioned leakage current in the N channel FET 170. In contrast to the above, no potential difference is caused between the lightly doped N region 185 with the applied voltage VDD and the support substrate 150 in the P channel FET 200, causing no leakage current.

Consequently, the aforesaid disadvantage due to the leakage current arises in any one of the N channel FET 170 and the P channel FET 200 which compose the CMOS transistor on the SOI substrate.

Moreover, not limited to the CMOS transistor, the same disadvantage arises in a semiconductor device in which N channel FETs and P channel FETs are provided in a mixed manner on an SOI substrate.

### SUMMARY OF THE INVENTION

The present invention is made to solve the above disadvantages which arise at the time when the semiconductor device (IC chip) using the SOI substrate is used, and an object thereof is to prevent occurrence of a leakage current in the semiconductor device regardless of a voltage applied to a support substrate made of silicon so as to accurately control a channel current.

The semiconductor device according to the present invention is characterized in that a semiconductor device in which a field effect transistor is formed on an SOI substrate provided with a surface silicon layer above a support substrate made of silicon with a buried oxidation film therebetween, comprising: a gate electrode provided above a component region, which is formed of the surface silicon layer of the SOI substrate and isolated, with a gate oxidation film therebetween; a lightly doped region of an N-type or a P-type formed in the component region; a source region formed of a conduction type different from that of the lightly doped region and formed shallow in the lightly doped region such that a back surface thereof does not contact the buried oxidation film; an offset drain region formed on the opposite side to the source region across the gate electrode in the component region and formed of a conduction type different from that of the lightly doped region; and a drain region formed in the offset drain region without contacting the gate oxidation film and formed of the same conduction type as that of the offset drain region.

In the above semiconductor device, it is preferable that the offset drain region is formed deep such that a back surface thereof contacts the buried oxidation film.

In any semiconductor devices, it is preferable that a channel doped layer having an impurity concentration or a conduction type different from that of the lightly doped region is formed under the gate oxidation film in the component region.

Further, in the semiconductor device, it is preferable that the channel doped layer is formed to have an impurity concentration lower than that in the lightly doped region, and, more preferably, formed of a conduction type different from that of the lightly doped region.

The above and other objects, features and advantages of the invention will be apparent from the following detailed description which is to be read in conjunction with the accompanying drawings.

### BRIEF DESCRIPTION OF THE DRAWINGS

FIG. 1 is a schematic sectional view showing an enlarged principal portion of a semiconductor device according to the present invention;

FIG. 2 is a schematic sectional view showing an enlarged principal portion of a CMOS transistor composed of the semiconductor device shown in FIG. 1 and a semiconductor device having a conduction type different from that of the semiconductor device shown in FIG. 1;

FIG. 3 is a schematic sectional view showing the relationship in depth between a lightly doped P region and an N source region of the semiconductor device shown in FIG. 1;

FIG. 4 is a schematic sectional view for explaining the depth of an offset drain region;

FIG. 5 is a schematic sectional view for explaining the depth of an offset drain region having a different depth;

FIG. 6 is a schematic sectional view showing an enlarged principal portion of a conventional semiconductor device using an SOI substrate;

FIG. 7 is a sectional view showing a principal portion of the conventional semiconductor device with a CMOS structure using an SOI substrate;

FIG. 8 is a sectional view showing an enlarged principal portion of a P channel FET for explaining the disadvantage of the semiconductor device shown in FIG. 7; and

FIG. 9 is a sectional view showing a more enlarged principal portion of the same P channel FET.

### DETAILED DESCRIPTION OF THE PREFERRED EMBODIMENTS

Hereinafter the preferred embodiments of the present invention will be described in detail using the drawings.

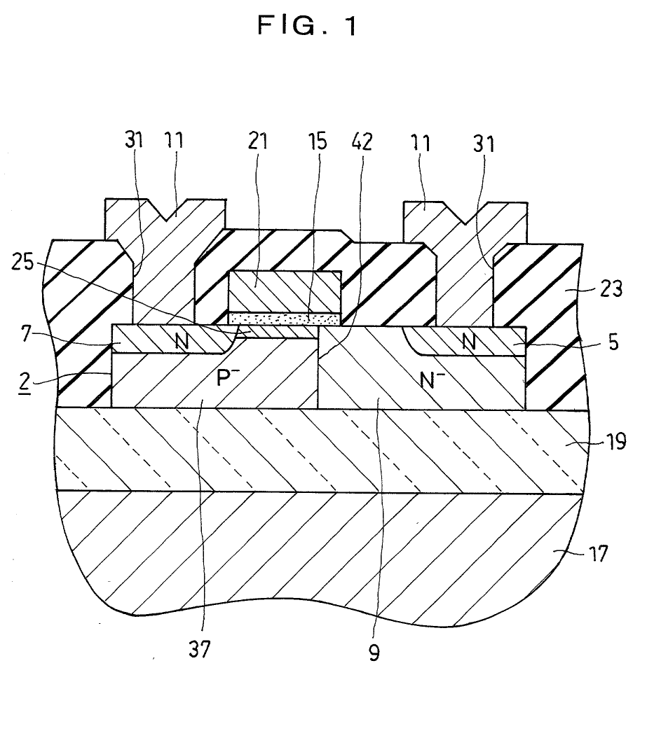

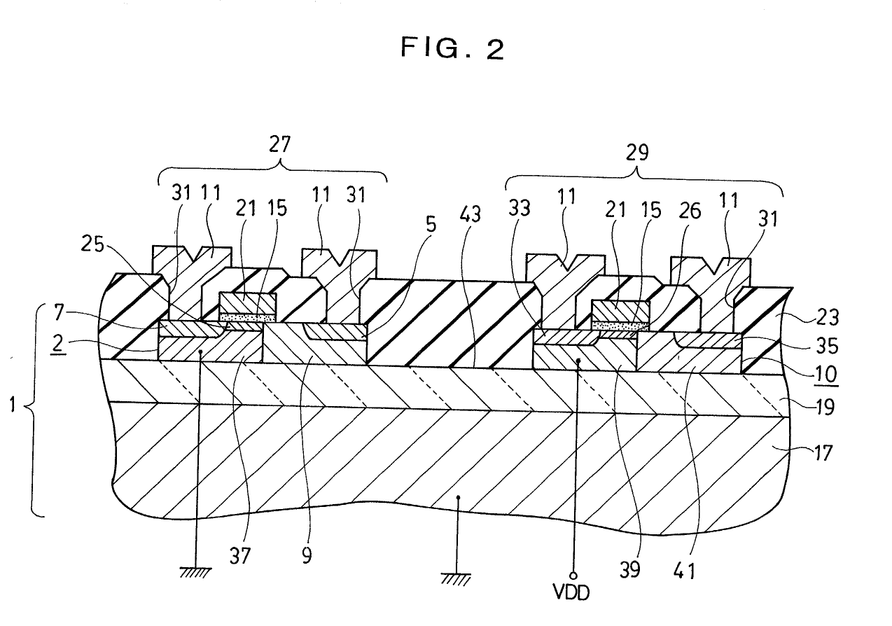

FIG. 1 is a schematic sectional view showing an enlarged principal portion of a semiconductor device according to the present invention, in which a portion of an N channel FET of a CMOS transistor shown in FIG. 2 is enlarged and the other portion is omitted. FIG. 2 is a schematic sectional view showing an enlarged principal portion of the semiconductor devices, in which the CMOS transistor is formed of the N channel FET and a P channel FET.

The semiconductor devices use an SOI substrate 1 made by providing a surface silicon layer on a buried oxidation film 19 formed on a support substrate 17 made of silicon, in which the surface silicon layer is partially removed to form a plurality of separate island-shaped component regions. Impurities are implanted and diffused in the component regions to form a P component region 2 and an N component region 10 respectively. An N channel FET 27 is provided on the P component region 2 and a P channel FET 29 is provided on the N component region 10. The N channel FET 27 and the P channel FET 29 are isolated from each other by an insulating film 23 made of a silicon oxidation film which is doped with boron atoms and phosphorus atoms. It should be noted that a large number of MOSFETs, not shown, identical to the N channel FETs 27 and the P channel FETs 29 serving as the semiconductor devices are provided respectively to form an IC chip. In addition to a large number of CMOS transistors, other FETs, bipolar transistors, resistors, capacitors, and so on are provided in an actual IC chip. The N channel FET 27 is mainly explained in the following explanation.

The buried oxidation film 19 has a film thickness of about 0.1 μm to about 5 μm, preferably about 1 μm. The surface silicon layer on the buried oxidation film 19 is formed to have a film thickness of about 0.1 μm to about 2 μm, preferably about 1 μm.

The component regions are formed of the surface silicon layer, and the area in which P impurities are implanted and diffused is the P component region 2 and the area in which N impurities are implanted and diffused is the N component region 10.

In the N channel FET 27, a gate electrode 21 is provided in the P component region 2 with a gate oxidation film 15 therebetween. Further, the N channel FET 27 is provided with: a lightly doped P region 37 formed in the P component region 2; an N source region 7 which is formed in the lightly doped P region 37 and formed of a conduction type different from that of the lightly doped P region 37; an N offset drain region 9 which is formed on the opposite side to the N source region 7 across the gate electrode 21 in the P component region 2 and formed of a conduction type (N-type) different from that of the lightly doped P region 37; and an N drain region 5 which is formed in the N offset drain region 9 without contacting the gate oxidation film 15 and formed of the same conduction type as that of the N offset drain region 9. A channel doped layer 25 is formed at a part formed with no N source region 7 in a surface which is not in contact with the buried oxidation film 19 between the N source region 7 and the N offset drain region 9 in the lightly doped P region 37. The channel doped layer 25 is formed under the gate oxidation film 15 in contact therewith.

The N source region 7 and the N drain region 5 are provided with metal electrodes 11 at the respective upper surfaces. Each of the metal electrodes 11 is electrically connected to the N source region 7 or the N drain region 5 through a contact hole 31, and is provided extending onto the insulating film 23.

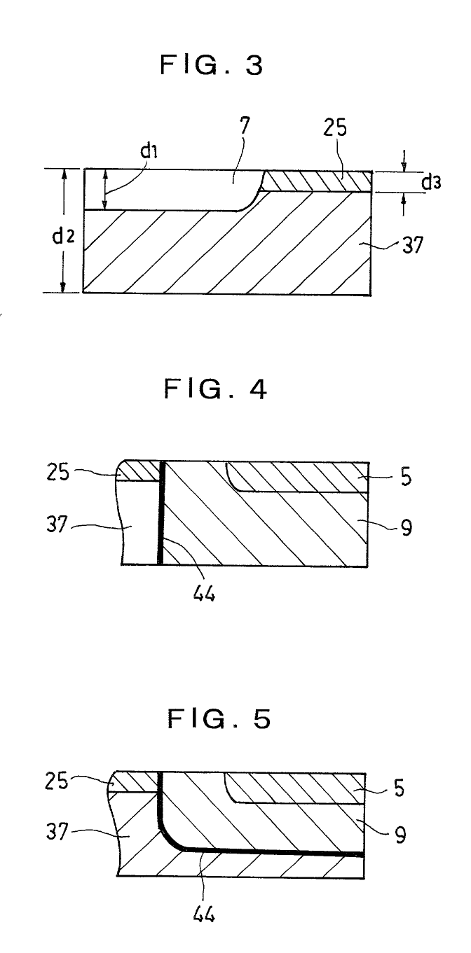

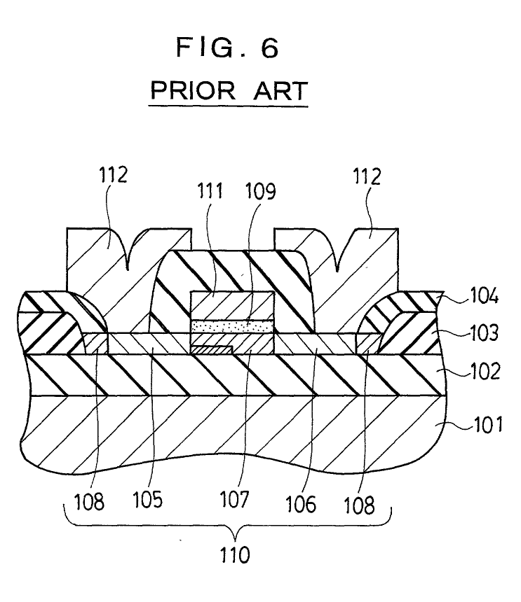

The N source region 7 and the N drain region 5 are formed shallow such that respective back surfaces do not contact the buried oxidation film 19. In the case of the N source region 7, a diffusion depth dl is about 0.2 μm as shown in FIG. 3. When the surface silicon layer is formed to have a thickness of about 1 μm as described above, a thickness d2 of the lightly doped P region 37 is the same as that, about 1 μm. This leads to the fact that the N source region 7 is formed to have a depth about one fifth the lightly doped P region 37 (the thickness of the N source region 7 is illustrated thicker than actual for convenience of illustration). It should be noted that the N source region 7 and the N drain region 5, for which arsenic atoms are used as the impurities, have a surface impurity concentration of about 1×10²⁰ atoms/cc.

The N offset drain region 9 is formed deep such that its back surface contacts the buried oxidation film 19. More specifically, the N offset drain region 9 is formed such that impurities (phosphorus atoms) are diffused to contact the buried oxidation film 19, so as to have the same diffusion depth as the thickness d2 of the lightly doped P region 37. It should be noted that the N offset drain region 9 has an impurity concentration lower than that in the source region, about 8×10¹⁶ atoms/cc.

The channel doped layer 25 is formed by implanting and diffusing phosphorus atoms therein as impurities to have a depth d3 of about 0.05 μm to which the impurities are diffused, and have a surface impurity concentration of about 5×10¹⁶ atoms/cc which is lower than that in the N source region 7. Change of the conduction type of the channel doped layer 25 and concentration of the impurities implanted thereto enables adjustment of the threshold voltage, the explanation thereof being made in more detail below.

Aluminum is used for the metal electrode 11. The gate oxidation film 15 is made of a silicon oxidation film and has a thickness of about 120 nm. The gate electrode 21 is made of polycrystalline silicon. Incidentally, since a metal electrode (interconnection electrode) connecting with the gate electrode 21 is provided at a position in a section different from FIG. 1, it is not shown in FIG. 1. Moreover, pad portions for providing input/output terminals are formed at the metal electrodes 11 connecting with the outside among a large number of metal electrodes 11 though the illustration thereof is omitted.

In the P channel FET 29, a gate electrode 21 is provided in the N component region 10 with a gate oxidation film 15 therebetween. Further, the P channel FET 29 is provided with: a lightly doped N region 39 formed in the N component region 10; a P source region 33 which is formed in the lightly doped N region 39 and formed of a conduction type different from that of the lightly doped N region 39; a P offset drain region 41 which is formed on the opposite side to the P source region 33 across the gate electrode 21 in the N component region 10 and formed of a conduction type (P-type) different from that of the lightly doped N region 39; and a P drain region 35 which is formed in the P offset drain region 41 without contacting the gate oxidation film 15 and formed of the same conduction type as that of the P offset drain region 41. A channel doped layer 26 is formed at a part formed with no P source region 33 in a surface which is not in contact with the buried oxidation film 19 between the P source region 33 and the P offset drain region 41 in the lightly doped N region 39. The channel doped layer 26 is formed in contact with the gate oxidation film 15 and below the gate electrode 21.

The P source region 33 and the P drain region 35 are provided with metal electrodes 11 at the respective upper surfaces. Each of the metal electrodes, 11 is electrically connected to the P source region 33 or the P drain region 35 through a contact hole 31, and is provided extending onto the insulating film 23.

As described above, the N channel FET 27 and the P channel FET 29 are merely inverse in conduction type of the P component region 2 and the N component region 10, and they have a common basic structure.

In each of the N channel FET 27 and the P channel FET 29, the drain region and the gate electrode are separated from each other, and the offset drain region with an impurity concentration lower than that in the drain region is provided to form an offset MOSFET. Since the drain region and the lightly doped region are of the P or N conduction type, they can form a PN junction, but the offset drain region is provided between them. Therefore, the offset MOSFET such as an N channel FET 27 has a structure in which a depletion layer generally easily grows when the drain region and the lightly doped region are reversely biased. Thus, the semiconductor device shown in FIG. 1 is a MOSFET with high breakdown voltage usable at a high voltage. Incidentally, the drain breakdown voltage of the N channel FET 27 is about 40V to about 50V.

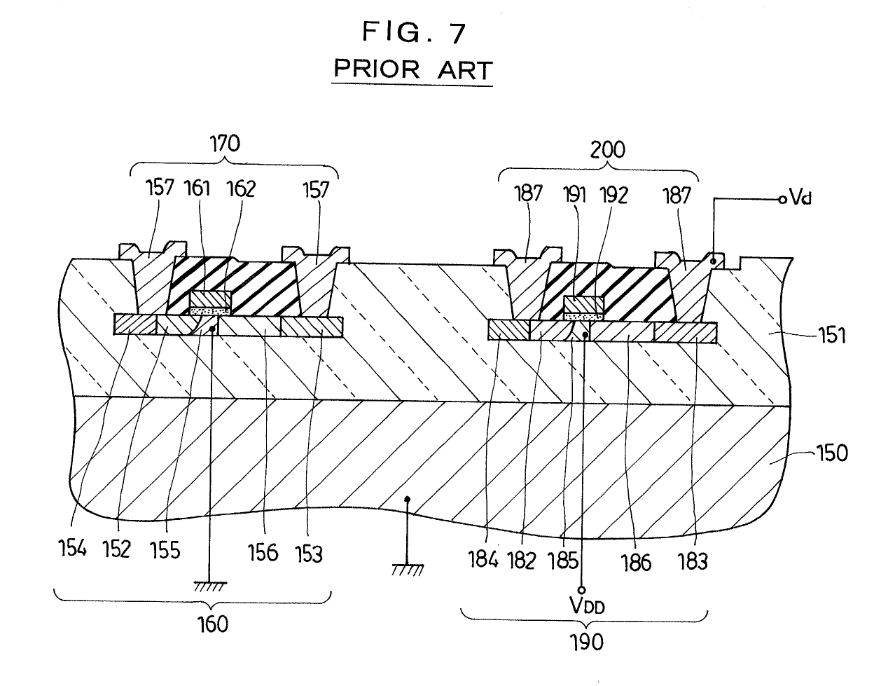

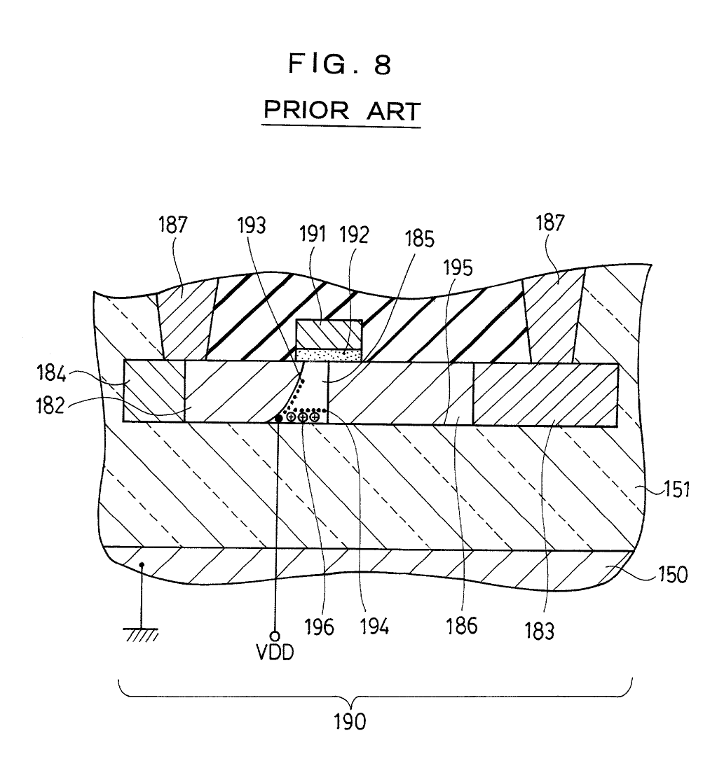

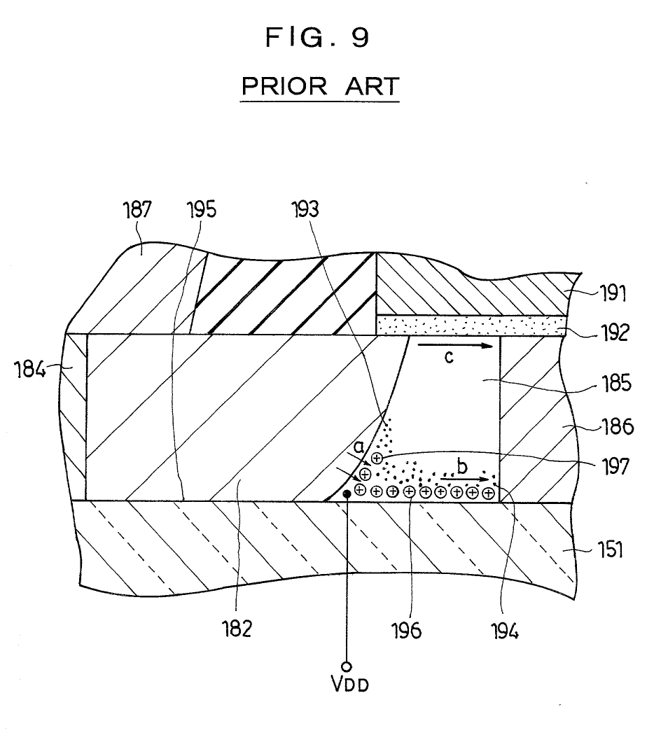

In the above-described semiconductor device according to the present invention, the N source region 7 is formed shallow in a manner not to come into contact with the buried oxidation film 19. The conventional semiconductor device shown in FIG. 7 differs from the above in that the N source region 152 is formed deep to contact the buried oxidation film 151. In the case of the conventional semiconductor device, as described above, carriers are supplied from the source region to cause a leakage current flowing in the back channel, and the supply of the carriers is promoted because of the great depth of the source region and the source region being in contact with the buried oxidation film. In the semiconductor device according to the invention, however, the supply of the carriers from the source region is suppressed because the source region is formed shallow in a manner not to come into contact with the buried oxidation film. The suppression of the supply of the carriers leads to suppression of occurrence of the leakage current flowing in the back channel, which enables accurate control of the channel current flowing in the front channel by the voltage applied to the gate electrode.

On the other hand, in the semiconductor device according to the invention, impurities are implanted and diffused in the surface silicon layer to form each component region, and the impurity concentration in the lightly doped region is determined by the impurity concentration in each component region. Accordingly, the concentration in the lightly doped region can be increased (raised) by adjusting the impurity concentration in each component when formed. For example, in the case of the lightly doped P region 37, treatment is performed using boron atoms as the P impurities under implanting conditions of 7×10¹² atoms/cm² implantation dose and 25 keV implantation energy, and diffusing conditions of about three hours at a temperature of about 1050° C. in a nitrogen atmosphere. The final impurity concentration is about 4×10¹⁶ atoms/cc.

When the semiconductor device with the buried oxidation film 19 having a film thickness of about 1 μm is used at an applied voltage of about 30V, the impurity concentration at this level (4×10¹⁶ atoms/cc) is necessary for the lightly doped region. However, since the impurity concentration need to be further increased when the semiconductor device is used at an applied voltage higher than 30V (for example, at about 60V), the impurity concentration in the lightly doped region needs to be adjusted in accordance with the applied voltage.

For example, in the case of the lightly doped P region 37, if its impurity concentration is increased, a depletion layer formed near a boundary surface 43 between the lightly doped P region 37 and the buried oxidation film 19 and a depletion layer formed near the boundary surface between the lightly doped P region 37 and the source region hardly grow even when a potential difference is produced between the lightly doped region and the support substrate, which avoids both depletion layers from joining together. Therefore, even if an inversion layer is formed in the buried oxidation film 19 near the boundary surface 43, a potential barrier between the lightly doped region and the source region is maintained in either the N channel FET 27 or the P channel FET 29. If the potential barrier is maintained and when the voltage applied to the lightly doped region is fixed, the supply of carriers from the source region is suppressed, which suppresses the occurrence of the leakage current flowing in the back channel more efficiently. This enables more accurate control of the channel current flowing in the front channel by the voltage applied to the gate electrode 21 (gate voltage).

The increase in the impurity concentration in the lightly doped region as describe above, however, increases the threshold voltage for operating the front channel (for flowing the channel current in the front channel). As a result, the voltage applied to the gate electrode 21 required to operate the front channel also increases to delay switching operation of both of the N channel FET 27 and the P channel FET 29.

For this reason, the semiconductor devices according to the invention is provided with the channel doped layers 25 and 26 in order to eliminate such a disadvantage. The channel doped layers 25 and 26 allow the threshold voltage for flowing the channel current to be adjustable by adjusting the impurity concentrations thereof. In other words, the voltage applied to the gate electrodes 21 can be suppressed to be low by the impurity concentration in the channel doped layers 25 and 26, which prevents the switching operation of the gate electrodes 21 from being delayed.

When the impurity concentration in the channel doped layers 25 and 26 is set low, the threshold voltage slightly decreases and can be kept at a relatively high level. In contrast to the above, when the impurity concentration in the channel doped layers 25 and 26 is set high, the threshold voltage greatly decreases to have a low value. The threshold voltage can be adjusted by the impurity concentration in the channel doped layers 25 and 26 as described above so as not to delay the switching operation of the gate electrodes 21, which makes it possible to set the impurity concentration in the lightly doped region high without the threshold voltage being affected thereby. The concrete concentration in the channel doped layers 25 and 26 may be adjusted as required in accordance with the operating status.

For example, when the impurity concentration in the channel doped layer 25 is set lower than that in the lightly doped P region 37 (for example, at about 2×10¹⁶ atoms/cc), such operation and effect can be obtained that the threshold voltage decreases to accelerate the switching operation. In this case, the conduction type of the channel doped layer 25 is the P-type that is the same as that of the lightly doped P region 37. When the threshold voltage needs to be decreased, the impurity concentration in the channel doped layer 25 is preferably set higher than that in the lightly doped P region 37 (for example, at about 5×10¹⁶ atoms/cc). In this case, the conduction type of the channel doped layer 25 is the N-type that is different from that of the lightly doped P region 37. In this manner, the threshold voltage is preferably adjusted in accordance with the purpose of a semiconductor device.

Meanwhile, in the semiconductor device according to the invention, the offset drain region may be formed shallow so that the back surface thereof does not contact the buried oxidation film 19, however, if the offset drain region is formed deep so that the back surface thereof contacts the buried oxidation film 19 as described above, the following operation and effect can be presented. For example, the case in which the N offset drain region 9 is formed deep so that the back surface thereof contacts the buried oxidation film 19 as shown in FIG. 4, is compared to the case in which the N offset drain region 9 is formed shallow so that the back surface thereof does not contact the buried oxidation film 19 as shown in FIG. 5. The fact is found that sizes of PN junctions formed at boundary surfaces 44 (thick line portions in FIG. 4 and FIG. 5) between the N offset drain regions 9 and the lightly doped P regions 37, greatly differ from each other. Since a parasitic capacitance exists along the PN junction, the power consumption is greatly affected by charge and discharge of the parasitic capacitance in the case of a large size PN junction as shown in FIG. 5, which causes a great delay in the switching operation. On the other hand, if the N offset drain region 9 is formed deep so that the back surface thereof contacts the buried oxidation film 19 as shown in FIG. 4, the size of the PN junction decreases to reduce the magnitude of the parasitic capacitance existing there, which can reduce the influence by the charge and discharge of the parasitic capacitance to a minimum.

Effect of the Invention

As has been described above, in the semiconductor device according to the present invention, since the source region of the field effect transistor of the N-type or the P-type formed on the SOI substrate is formed shallow in a manner not to come into contact with the buried oxidation film, the depletion layer growing from the source region side never joins to the depletion layer growing from the buried oxidation film even when there is a potential difference between the lightly doped region and the support substrate. Further, if the impurity concentration in the lightly doped region is set high, the growing of the depletion layer can be suppressed more efficiently. Therefore, carriers are never supplied to the inversion layer from the source region, producing no leakage current flowing in the back channel, resulting in accurate control of the channel current by the gate voltage.

Moreover, formation of the channel doped layer enables the threshold voltage to adjust by adjusting the impurity concentration in the channel doped layer even if the impurity concentration in the lightly doped region is set high, which makes it possible to depress the voltage applied to the gate electrode to be low and to prevent the switching operation of the gate electrode from being delayed.

What is claimed is:

1. A semiconductor device in which a field effect transistor is formed on an SOI substrate provided with a surface silicon layer above a support substrate made of silicon with a buried oxidation film therebetween, comprising:
a gate electrode provided above a component region, which is formed of said surface silicon layer of said SOI substrate and isolated, with a gate oxidation film therebetween;
a lightly doped region of an N-type or a P-type formed in said component region;
a source region formed of a conduction type different from that of said lightly doped region and formed shallow in said lightly doped region such that a back surface thereof does not contact the buried oxidation film;
an offset drain region formed on the opposite side to said source region across said gate electrode in said component region and formed of a conduction type different from that of said lightly doped region; and
a drain region formed in said offset drain region without contacting said gate oxidation film and formed of the same conduction type as that of said offset drain region.

2. A semiconductor device according to claim 1, wherein said offset drain region is formed deep such that a back surface thereof contacts said buried oxidation film.

3. A semiconductor device according to claim 1, wherein a channel doped layer having an impurity concentration or a conduction type different from that of said lightly doped region is formed under said gate oxidation film in said component region.

4. A semiconductor device according to claim 2, wherein a channel doped layer having an impurity concentration or a conduction type different from that of said lightly doped region is formed under said gate oxidation film in said component region.

5. A semiconductor device according to claim 3, wherein said channel doped layer is formed to have an impurity concentration lower than that in said lightly doped region.

6. A semiconductor device according to claim 4, wherein said channel doped layer is formed to have an impurity concentration lower than that in said lightly doped region.

7. A semiconductor device according to claim 5, wherein said channel doped layer is formed of a conduction type different from that of said lightly doped region.

8. A semiconductor device according to claim 6, wherein said channel doped layer is formed of a conduction type different from that of said lightly doped region.
